(19) United States
(12) Patent Application Publication
(10) Pub. No.: US 2015/0155019 A1
(43) Pub. Date: Jun. 4, 2015

(54) SEMICONDUCTOR INTEGRATED CIRCUIT

(71) Applicant: SK hynix Inc., Icheon-si Gyeonggi-do (KR)

(72) Inventor: Min Chang KIM, Icheon-si Gyeonggi-do (KR)

(73) Assignee: SK hynix Inc., Icheon-si Gyeonggi-do (KR)

(21) Appl. No.: 14/186,440

(22) Filed: Feb. 21, 2014

(30) Foreign Application Priority Data
Nov. 29, 2013 (KR) 10-2013-0147152

(51) Int. Cl. G11C 7/22; G11C 7/10

(52) U.S. Cl. CPC G11C 7/222; G11C 7/1087

(57) ABSTRACT

A semiconductor integrated circuit includes a data latch unit configured to latch arranged data according to a domain crossing control signal, and to output the arranged data as write data; and a domain crossing controller configured to generate the domain crossing control signal with respect to the timing of a data strobe signal.

### CROSS-REFERENCES TO RELATED APPLICATION

The present application claims priority under 35 U.S.C. §119(a) to Korean application number 10-2013-0147152, filed on Nov. 29, 2013, in the Korean Intellectual Property Office, which is incorporated herein by reference in its entirety.

### BACKGROUND

1. Technical Field

Various embodiments relate to a semiconductor circuit, and more particularly, to a semiconductor integrated circuit.

2. Related Art

A semiconductor integrated circuit may operate in a multi-bit prepatch scheme.

On a read operation, data of cells in a memory block is read at a time point, and is then outputted in regular sequence; and on a write operation, successively inputted data is arranged, and is then stored in a memory block at a time point.

In this case, data input/output of a semiconductor integrated circuit is performed in synchronization with an external data strobe signal DQS, but, after a predetermined processing zone, internal data may be processed in synchronization with a clock signal CLK.

Therefore, a domain crossing operation of synchronizing data, which has been synchronized with an external data strobe signal DQS, with a clock signal CLK may be required in a semiconductor integrated circuit.

The domain crossing operation is required to satisfy tDQSS which is a standard that defines a difference in the timing between the clock signal CLK and the external data strobe signal DQS.

### SUMMARY

In an embodiment, a circuit may include: a data strobe domain block configured to receive an external data strobe signal and arrange data using the external data strobe signal, and to generate arranged data; a data latch unit configured to latch the arranged data according to a domain crossing control signal, and to output the arranged data as write data; and a domain crossing controller configured to generate the domain crossing control signal with respect to the timings of the external data strobe signal.

In an embodiment, a circuit may include: a data latch unit configured to latch arranged data according to a domain crossing control signal, and to output the arranged data as write data; and a domain crossing controller configured to generate the domain crossing control signal with respect to the timing of a data strobe signal.

In an embodiment, a system may include: a processor; a chipset configured to couple with the processor; a controller configured to receive a request provided from the processor through the chipset; and a memory device configured to receive the request and output data to the controller, the controller including: a data latch unit configured to latch arranged data according to a domain crossing control signal, and to output the arranged data as write data; and a domain crossing controller configured to generate the domain crossing control signal with respect to the timing of a data strobe signal.

### BRIEF DESCRIPTION OF THE DRAWINGS

Features, aspects, and embodiments are described in conjunction with the attached drawings, in which:

FIG. 1 is a block diagram illustrating the configuration of a semiconductor integrated circuit according to an embodiment;

FIG. 2 is a timing diagram illustrating the operation of the semiconductor integrated circuit according to an embodiment;

FIG. 3 is a block diagram illustrating the configuration of a semiconductor integrated circuit according to an embodiment;

FIG. 4 is a circuit diagram illustrating the internal configuration of a write reference signal generation unit capable of being implemented in the circuit of FIG. 3;

FIG. 5 is a circuit diagram illustrating the configuration of a sensing unit capable of being implemented in the circuit of FIG. 3; and

FIG. 6 is a timing diagram illustrating the operation of the semiconductor integrated circuit according to an embodiment.

FIG. 7 illustrates a block diagram of a system employing semiconductor integrated circuit in accordance with the embodiments discussed above with relation to FIGS. 1-6.

### DETAILED DESCRIPTION

Hereinafter, a semiconductor integrated circuit will be described below with reference to the accompanying drawings through various examples of embodiments.

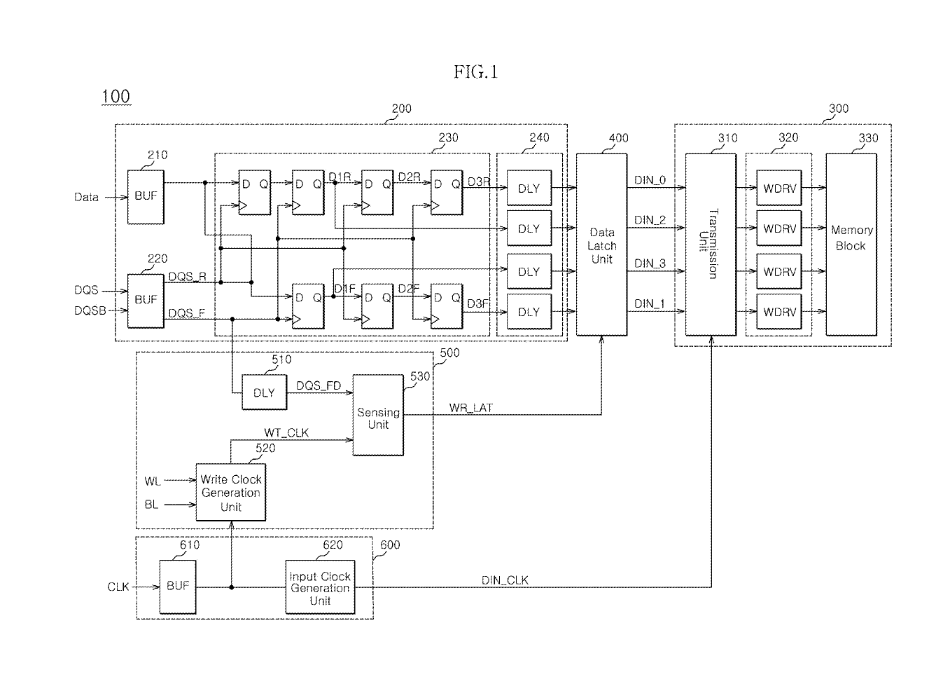

As illustrated in FIG. 1, a semiconductor integrated circuit 100 according to an embodiment may include a data strobe domain block 200, a clock domain block 300, a data latch unit 400, a domain crossing controller 500, and a clock path 600.

The data strobe domain block 200 may be configured to arrange Data using external data strobe signals DQS and DQSB.

The data strobe domain block 200 may include buffers 210 and 220, a data arrangement unit 230, and a delay unit 240.

The buffer 210 may be configured to buffer and output Data provided from an exterior.

The buffer 220 may be configured to buffer and output the external data strobe signals DQS and DQSB as internal data strobe signals DQS_R and DQS_F. The buffer cannot perceive the data strobe signal DQS when the data strobe signal DQS is at HI-Z state, since the level of the data strobe signal DQS at HI-Z state is neither logic high or logic low.

The internal data strobe signals DQS_R and DQS_F may be signals which are synchronized with the rising edge and falling edge of the external data strobe signal DQS, respectively.

The data arrangement unit 230 may be configured to arrange Data using the internal data strobe signals DQS_R and DQS_F and to output the arranged data D1R, D1F, D3R and D3F.

The data arrangement unit 230 may have a pipe latch structure, and may include a plurality of flip-flops.

The delay unit 240 may be configured to delay and output the arranged data outputted from the data arrangement unit 230.

The delay unit 240 may include a plurality of delay units DLYs.

The clock domain block 300 may be configured to write write data DIN<0:3> in a memory block 330 in response to an input clock signal DIN_CLK.

The clock domain block 300 may include a transmission unit 310, a write driver block 320, and the memory block 330.

The transmission unit 310 may be configured to transmission write data DIN<0:3> to the write driver block 320 in response to an input clock signal DIN_CLK.

The write driver block 320 may be configured to drive and store an output of the transmission unit 310 in the memory block 330.

The write driver block 320 may include a plurality of write drivers WDRVs.

The data latch unit 400 may be configured to latch the arranged data, which passes through the data strobe domain block 200, i.e. the delay unit 240, according to a domain crossing control signal WR_LAT, and to output the arranged data as write data DIN<0:3>.

The domain crossing controller 500 may be configured to generate the domain crossing control signal WR_LAT in response to the internal data strobe signal DQS_F, a clock signal CLK, a write latency signal WL, and a burst length signal BL.

The domain crossing controller 500 may include a delay unit 510, a write clock generation unit 520, and a sensing unit 530.

The delay unit 510 may be configured to delay the internal data strobe signal DQS_F by a set time, and to generate a delayed data strobe signal DQS_FD.

The write clock generation unit 520 may be configured to adjust the clock signal CLK in accordance with the burst length signal BL by shifting the clock signal CLK by a write latency corresponding to the write latency signal WL, and to output the adjusted clock signal as a write clock signal WT_CLK.

The sensing unit 530 may be configured to latch the write clock signal WT_CLK by the delayed data strobe signal DQS_FD, and to generate the domain crossing control signal WR_LAT.

In an embodiment write clock signal WT_CLK and the domain crossing control signal WR_LAT generated using the write clock signal WT_CLK may be far from the internal data strobe signal DQS_F in the physical distances within the semiconductor integrated circuit 100.

Therefore, in order to compensate for such a difference in delay time, the delay units 240 and 510 may be used and included.

The clock path 600 may be configured to generate the input clock signal DIN_CLK using the clock signal CLK provided from an exterior.

The clock path 600 may include a buffer 610 and an input clock generation unit 620.

The buffer 610 may be configured to buffer and output the clock signal CLK.

The input clock generation unit 620 may be configured to adjust the timing of an output signal of the buffer 610, and to generate the input clock signal DIN_CLK.

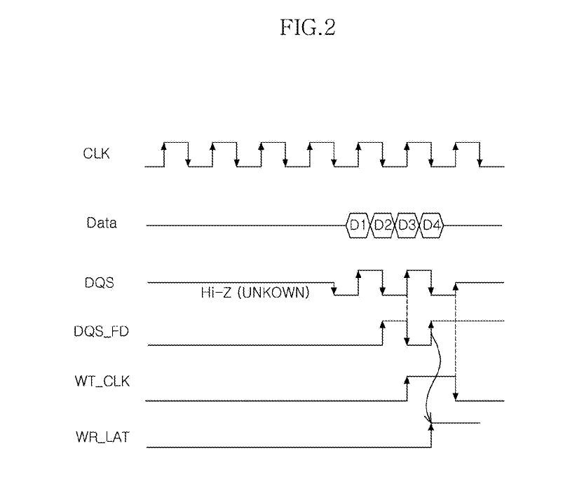

The operation of the semiconductor integrated circuit 100 having the aforementioned configuration according to an embodiment will be described below with reference to FIGS. 1 and 2.

After a write instruction is inputted and a set write latency elapses, Data D1-D4 is inputted.

In addition, together with the Data D1-D4, the external data strobe signal DQS is inputted.

In the domain crossing controller 500, the delay unit 510 delays the internal data strobe signal DQS_F by a set time, and generates a delayed data strobe signal DQS_FD.

The write clock generation unit 520 shifts a clock signal CLK by a write latency corresponding to a write latency signal WL so as to adjust the clock signal CLK in accordance with a burst length signal BL, and to generate a write clock signal WT_CLK.

The sensing unit 530 latches the write clock signal WT_CLK by a rising edge of the delayed data strobe signal DQS_FD, generates the domain crossing control signal WR_LAT.

Accordingly, the data latch unit 400 latches arranged data, which has been outputted in the domain of the external data strobe signal DQS from the data strobe domain block 200, according to the domain crossing control signal WR_LAT, and outputs the arranged data as write data DIN<0:3> converted into the domain of the clock signal CLK.[

The clock domain block 300 writes the write data DIN<0:3> in the memory block 330 in response to an input clock signal DIN_CLK.

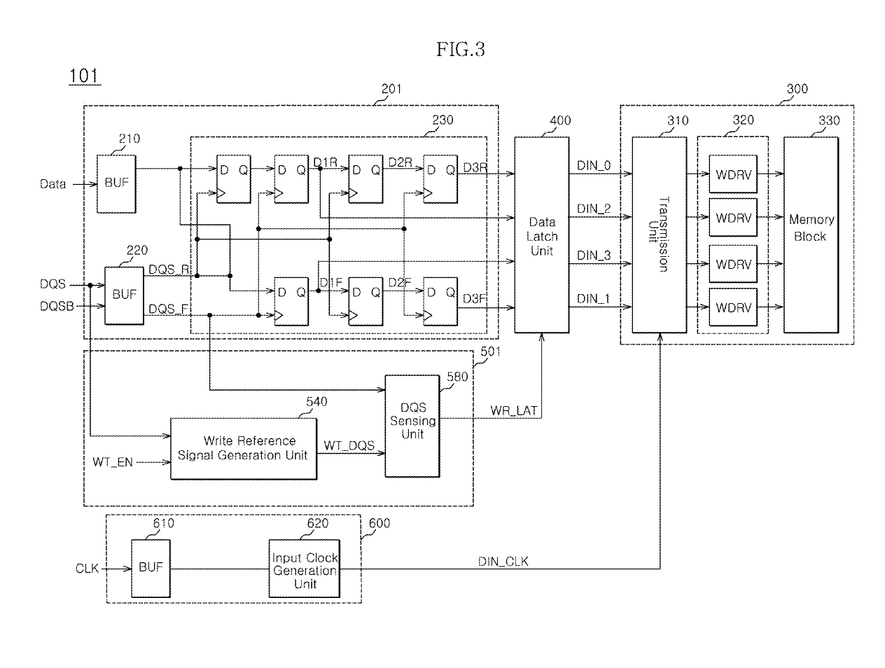

As illustrated in FIG. 3, a semiconductor integrated circuit 101 according to an embodiment may include a data strobe domain block 201, a clock domain block 300, a data latch unit 400, a domain crossing controller 501, and a clock path 600.

The data strobe domain block 201 may be configured to arrange Data using external data strobe signals DQS and DQSB, and to generate the arranged data.

The data strobe domain block 201 may include buffers 210 and 220, and a data arrangement unit 230.

The buffer 210 may be configured to buffer and output Data provided from an exterior.

The buffer 220 may be configured to buffer and output the external data strobe signals DQS and DQSB as internal data strobe signals DQS_R and DQS_F.

The internal data strobe signals DQS_R and DQS_F may be signals which are synchronized with the rising edge and falling edge of the external data strobe signal DQS, respectively.

The data arrangement unit 230 may be configured to arrange Data using the internal data strobe signals DQS_R and DQS_F and to generate the arranged data D1R, D1F, D3R and D3F.

The data arrangement unit 230 may have a pipe latch structure, and may include a plurality of flip-flops.

The clock domain block 300 may be configured to write write data DIN<0:3> in a memory block 330 in response to an input clock signal DIN_CLK.

The clock domain block 300 may include a transmission unit 310, a write driver block 320, and the memory block 330.

The transmission unit 310 may be configured to transmission write data DIN<0:3> to the write driver block 320 in response to an input clock signal DIN_CLK.

The write driver block 320 may be configured to drive and store an output of the transmission unit 310 in the memory block 330.

The write driver block 320 may include a plurality of write drivers WDRVs.

The data latch unit 400 may be configured to latch the arranged data, which are outputted from the data strobe domain block 201, according to a domain crossing control signal WR_LAT, and to output the arranged data as write data DIN<0:3>.

The domain crossing controller 501 may be configured to generate the domain crossing control signal WR_LAT with respect to the timings of the external data strobe signal DQS and internal data strobe signal DQS_F, regardless of a clock signal CLK.

The domain crossing controller 501 may be configured to the domain crossing control signal WR_LAT in response to a write enable signal WT_EN, the external data strobe signal DQS, and the internal data strobe signal DQS_F.

The domain crossing controller 501 may be configured to eliminate a termination zone of the external data strobe signal DQS and divide the external data strobe signal DQS using a write enable signal WT_EN, and to output the divided signal as the domain crossing control signal WR_LAT in matching with the timing of the internal data strobe signal DQS_F.

The domain crossing controller 501 may include a write reference signal generation unit 540 and a sensing unit 580 (i.e., data strobe sensing unit DQS Sensing Unit).

The write reference signal generation unit 540 may be configured to generate a write reference signal WT_DQS in response to the write enable signal WT_EN and the external data strobe signal DQS.

The write reference signal generation unit 540 may be configured to eliminate a termination zone of the external data strobe signal DQS and divide the external data strobe signal DQS in response to a write enable signal WT_EN, and to output the divided signal as a write reference signal WT_DQS.

The sensing unit 580 may be configured to latch the write reference signal WT_DQS by the internal data strobe signal DQS_F, and to generate the domain crossing control signal WR_LAT.

The clock path 600 may be configured to generate the input clock signal DIN_CLK using a clock signal CLK provided from an exterior.

The clock path 600 may include a buffer 610 and an input clock generation unit 620.

The buffer 610 may be configured to buffer and output the clock signal CLK.

The input clock generation unit 620 may be configured to adjust the timing of an output signal of the buffer 610, and to generate the input clock signal DIN_CLK.

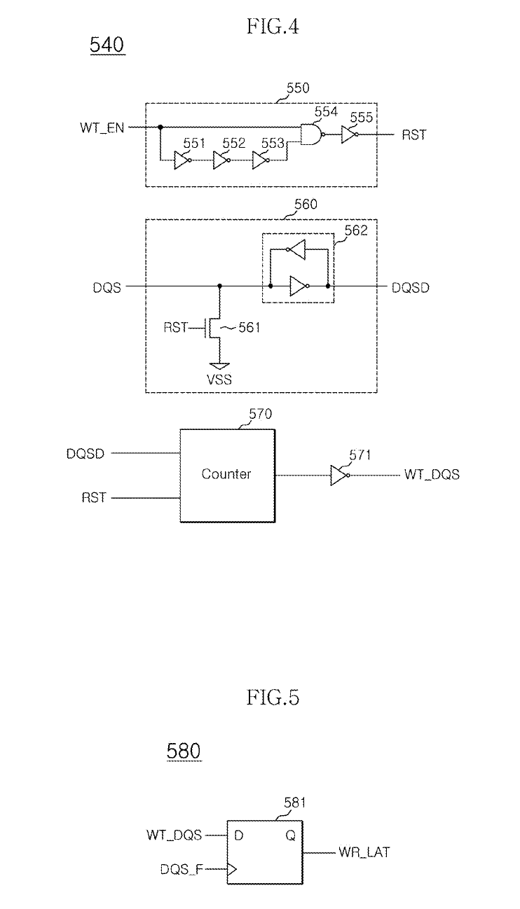

As illustrated in FIG. 4, the write reference signal generation unit 540 may include a reset signal generation unit 550, a termination zone elimination unit 560, and a counter 570.

The reset signal generation unit 550 may be configured to sense activation of a write enable signal WT_EN, and to generate a reset signal RST having a predetermined pulse width.

The reset signal generation unit 550 may be configured with a pulse generator including logic gates 551-555.

When the write enable signal WT_EN is activated, i.e.

transitions from a low level to a high level, the reset signal generation unit 550 transitions the reset signal RST to a high level, and then transitions the reset signal RST to a low level after the delay times of inverters 551-553 have elapsed.

The termination zone elimination unit 560 may be configured to output a signal DQSD, which is obtained by eliminating an initial termination zone of the external data strobe signal DQS using a reset signal RST.

The termination zone elimination unit 560 may include a transistor 561 and a latch 562.

The transistor 561 may have a drain electrically coupled to the transmission line of the external data strobe signal DQS, a gate configured to receive a reset signal RST, and a source configured to receive a ground voltage VSS.

The latch 562 may be configured in such a manner that the input terminal thereof is electrically coupled to the drain of the transistor 561, and the output terminal is configured to output a signal DQSD therethrough.

The counter 570 can output a write reference signal WT_DQS having a period 2tCK two times longer than that of the signal DQSD, which has been outputted from the termination zone elimination unit 560, by counting and inverting the signal DQSD through an inverter 571. The counter may also receive a reset signal RST for resetting the counter 570.

As illustrated in FIG. 5, the sensing unit 580 may include a flip-flop 581.

The sensing unit 580 may latch the write reference signal WT_DQS by the internal data strobe signal DQS_F, and output the latched signal as the domain crossing control signal WR_LAT with latch 581.

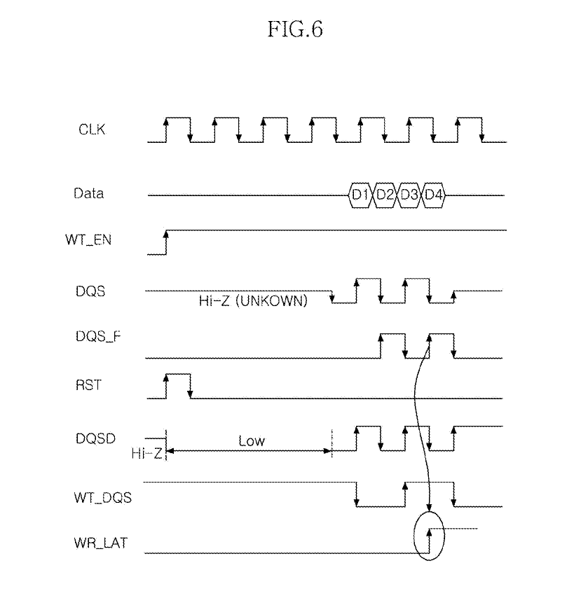

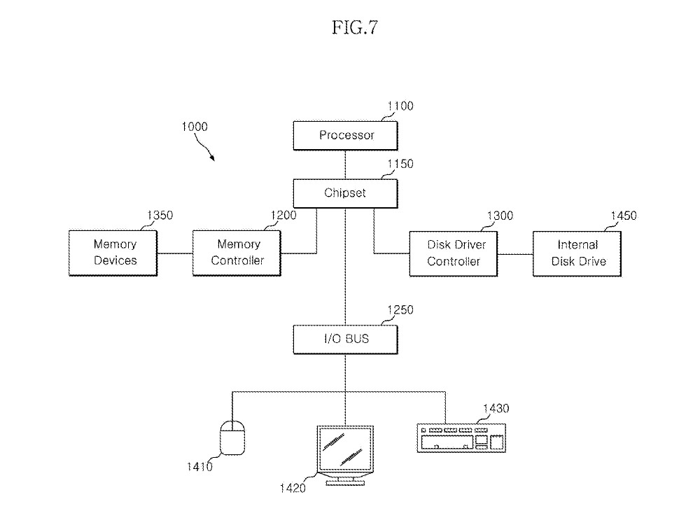

The operation of the semiconductor integrated circuit 101 having the aforementioned configuration according to an embodiment will be described below with reference to FIGS. 3 to 6.

After a write instruction is inputted and a set write latency elapses, Data D1-D4 is inputted.

In addition, together with the Data D1-D4, the data strobe signal DQS is inputted from an exterior.

Referring to FIG. 4, as a write enable signal WT_EN is activated, a reset signal RST is activated.

As the reset signal RST is activated, a signal DQSD obtained by eliminating an initial termination zone Hi-Z of the external data strobe signal DQS is generated.

The signal DQSD is counted and inverted, so that a write reference signal WT_DQS having a period 2tCK two times longer than that of the signal DQSD is generated.

The write reference signal WT_DQS is latched by the rising edge of the internal data strobe signal DQS_F, so that the domain crossing control signal WR_LAT is generated.

Accordingly, the data latch unit 400 latches data, which has been outputted in the domain of the external data strobe signal DQS from the data strobe domain block 201, according to the domain crossing control signal WR_LAT, and outputs write data DIN<0:3> converted into the domain of the clock signal CLK.

The clock domain block 300 writes the write data DIN<0:3> in the memory block 330 in response to an input clock signal DIN_CLK.

The technology may stably compensate for the difference in the timing between a clock signal and a data strobe signal.

The semiconductor integrated circuit discussed above is particular useful in the design of memory devices, processors, and computer systems. For example, referring to FIG. 7, a block diagram of a system employing a memory controller in accordance with the embodiments of the invention is illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one semiconductor integrated circuit as discussed above with reference to FIGS. 1-6. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the semiconductor integrated circuit 100 or 101 found in FIGS. 1-6, the memory devices 1350 may include a plurality of word lines and a plurality of bit lines for defining a plurality of memory cell. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 7 is merely one example of a system employing the semiconductor integrated circuit as discussed above with relation to FIGS. 1-6. In alternate embodiments, such as cellular phones or digital cameras, the components may differ from the embodiments shown in FIG. 7.

While certain embodiments have been described above, it will be understood to those skilled in the art that the embodiments described are by way of example only. Accordingly, the circuit described herein should not be limited based on the described embodiments. Rather, the circuit described herein should only be limited in light of the claims that follow when taken in conjunction with the above description and accompanying drawings.

What is claimed is:

1. A semiconductor integrated circuit comprising:
a data strobe domain block configured to receive an external data strobe signal and arrange data using the external data strobe signal, and to generate arranged data;
a data latch unit configured to latch the arranged data according to a domain crossing control signal, and to output the arranged data as write data; and
a domain crossing controller configured to generate the domain crossing control signal with respect to the timing of the external data strobe signal.

2. The semiconductor integrated circuit according to claim 1, further comprising:
a clock domain block configured to write the write data in a memory block in response to an input clock signal.

3. The semiconductor integrated circuit according to claim 1,
wherein the data strobe domain block includes a first buffer configured for receiving the external data strobe signal and generating an internal data strobe signal, and
wherein the domain crossing controller is configured to generate the domain crossing control signal with respect to the timings of the external data strobe signal and the internal data strobe signal.

4. The semiconductor integrated circuit according to claim 3, wherein the internal data strobe signal is a signal synchronized with a rising edge or a falling edge of the external data strobe signal.

5. The semiconductor integrated circuit according to claim 2, further comprising a clock path which is configured to generate the input clock signal using a clock signal received externally from the semiconductor integrated circuit.

6. The semiconductor integrated circuit according to claim 5, wherein the clock path comprises:
a buffer configured to buffer and output the clock signal; and
an input clock generation unit configured to adjust the timing of an output signal of the buffer, and to output the output signal of the buffer as the input clock signal.

7. The semiconductor integrated circuit according to claim 3, wherein the data strobe domain block comprises:
the first buffer configured to buffer the external data strobe signal, and to output the internal data strobe signal;
a second buffer configured to buffer and output the data; and
a data arrangement unit configured to arrange the data using the internal data strobe signal, and generate the arranged data.

8. The semiconductor integrated circuit according to claim 2, wherein the clock domain block comprises:
a write driver block configured to drive and store an input signal in the memory block; and
a transmission unit configured to transmission the write data as the input signal to the write driver block in response to the input clock signal.

9. The semiconductor integrated circuit according to claim 3, wherein the domain crossing controller is configured to generate the domain crossing control signal in response to a write enable signal, the external data strobe signal, and the internal data strobe signal.

10. The semiconductor integrated circuit according to claim 3, wherein the domain crossing controller is configured to eliminate a termination zone of the external data strobe signal and divide the external data strobe signal using a write enable signal, and to output the divided signal as the domain crossing control signal in matching with the timing of the internal data strobe signal.

11. The semiconductor integrated circuit according to claim 3, wherein the domain crossing controller comprises:
a write reference signal generation unit configured to eliminate a termination zone of the external data strobe signal and divide the external data strobe signal in response to a write enable signal, and to generate a write reference signal; and
a sensing unit configured to latch the write reference signal by the internal data strobe signal, and to output the latched signal as the domain crossing control signal.

12. The semiconductor integrated circuit according to claim 11, wherein the write reference signal generation unit comprises:
a reset signal generation unit configured to sense activation of the write enable signal, and to generate a reset signal having a predetermined pulse width;
a termination zone elimination unit configured to output a signal which is obtained by eliminating a termination zone of the external data strobe signal using the reset signal; and
a counter configured to divide the signal outputted from the termination zone elimination unit, and to output the write reference signal.

13. A semiconductor integrated circuit comprising:
a data latch unit configured to latch arranged data according to a domain crossing control signal, and to output the arranged data as write data; and
a domain crossing controller configured to generate the domain crossing control signal with respect to the timing of a data strobe signal.

14. The semiconductor integrated circuit according to claim 13, wherein the arranged data is arranged with respect to the data strobe signal.

15. The semiconductor integrated circuit according to claim 13, wherein the write data is written with respect to a clock signal.

16. The semiconductor integrated circuit according to claim 13, wherein the domain crossing controller is configured to generate the domain crossing control signal in response to a write enable signal, an external data strobe signal, and an internal data strobe signal.

17. The semiconductor integrated circuit according to claim 16, wherein the internal data strobe signal is a signal synchronized with a rising edge or a falling edge of the external data strobe signal.

18. The semiconductor integrated circuit according to claim 16, wherein the domain crossing controller is configured to eliminate a termination zone of the external data strobe signal and divide the external data strobe signal using the write enable signal, and to output the divided signal as the domain crossing control signal in matching with the timing of the internal data strobe signal.

19. The semiconductor integrated circuit according to claim 13, wherein the domain crossing controller comprises:
a write reference signal generation unit configured to eliminate a termination zone of the external data strobe signal and divide the external data strobe signal in response to a write enable signal, and to generate a write reference signal; and
a sensing unit configured to latch the write reference signal by the internal data strobe signal, and to output the latched signal as the domain crossing control signal.

20. The semiconductor integrated circuit according to claim 19, wherein the write reference signal generation unit comprises:
a reset signal generation unit configured to sense activation of the write enable signal, and to generate a reset signal having a predetermined pulse width;
a termination zone elimination unit configured to output a signal which is obtained by eliminating a termination zone of the external data strobe signal using the reset signal; and
a counter configured to divide the signal outputted from the termination zone elimination unit, and to output the write reference signal.
